(19) United States
(12) Patent Application Publication
(10) Pub. No.: US 2020/0075457 A1
(43) Pub. Date: Mar. 5, 2020

(54) SEMICONDUCTOR DEVICE AND FABRICATION METHOD THEREOF

(71) Applicant: Wuhan Xinxin Semiconductor Manufacturing Co., Ltd., Hubei (CN)

(72) Inventor: Xing HU, Hubei (CN)

(21) Appl. No.: 16/230,188

(22) Filed: Dec. 21, 2018

(30) Foreign Application Priority Data
Aug. 28, 2018 (CN) 201810989732.6

(51) Int. Cl. H01L 23/48; H01L 21/306; H01L 21/768

(52) U.S. Cl. CPC H01L 23/481; H01L 21/76898; H01L 21/306

(57) ABSTRACT

A semiconductor device and a fabrication method thereof are disclosed. In the semiconductor device, a first opening penetrates through a first substrate and is located above a first metal layer; a second opening penetrates through the first substrate, a first dielectric layer and a partial thickness of a second dielectric layer and is located above a second metal layer; an interconnection layer, formed in the first opening and the second opening, wherein the interconnection layer is electrically connected with the first and second metal layers; and a lead-out layer, formed over the first wafer, wherein the lead-out layer is electrically connected with the interconnection layer in the first and second openings.

### CROSS-REFERENCE TO RELATED APPLICATION

This application claims the priority of Chinese patent application number 201810989732.6, filed on Aug. 28, 2018, the entire contents of which are incorporated herein by reference.

### TECHNICAL FIELD

The present invention relates to the technical field of integrated circuit manufacturing and, in particular, to a semiconductor device and a fabrication method thereof.

### BACKGROUND

Through Silicon Via (TSV) technology is a new technology making vertical conductions between chip and chip, and between wafer and wafer so as to achieve interconnections between the chips, and enable a larger stacking density in a three-dimensional direction.

A TSV nested opening structure is commonly adopted in the TSV technology, and the TSV nested opening structure is a structure having a deep opening used together with a shallow opening. Three photomasks, and hence three etchings, are needed to form the TSV nested opening structure. The TSV nested opening structure can meet, to a very large extent, a metal interconnection requirement after bonding. However, the inventor finds that, in practical applications, limitation of the TSV nested opening structure becomes increasingly obvious. Specifically, the TSV nested opening structure achieves connection of metal layers of upper and lower wafers through a TSV nested opening interconnected in a longitudinal direction; during a design, the distribution of the metal layers of the upper and lower wafers is limited and constrained by the transverse fabrication process of the TSV nested opening interconnected in the longitudinal direction. For example, a transverse distance of the metal layers of the upper and lower wafers cannot be too far. If the transverse distance of the metal layers of the upper and lower wafers is too far, an effective area of the upper wafer is wasted for the TSV connection. Meanwhile, with an increased depth-to-width ratio of the deep opening, a difficulty in the filling and removing of a filling layer in the deep opening is also increased.

### SUMMARY OF THE INVENTION

The present invention is directed to provide a semiconductor device fabrication method and a semiconductor device, so as to solve the problem of a low flexibility for the design of a wafer employing a TSV nested opening structure. The present invention may also solve the problem of an increased difficulty for the fabrication process caused by an increased depth-to-width ratio of a deep opening.

In order to solve the above technical problems, the present invention provides a method for fabricating a semiconductor device, comprising:

providing a first wafer and a second wafer that are bonded together, wherein the first wafer comprises a first substrate, a first dielectric layer and a first metal layer; the second wafer comprises a second substrate, a second dielectric layer and a second metal layer, the first dielectric layer facing the second dielectric layer;

performing a first etching process to form a first opening, wherein the first opening penetrates through the first substrate, the first opening located above the first metal layer;

forming a filling layer, wherein the first opening is filled with the filling layer;

performing a second etching process to form a second opening, wherein the second opening penetrates through the first substrate, the first dielectric layer and a partial thickness of the second dielectric layer, the second opening located above the second metal layer;

performing a third etching process to deepen the first and second openings such that the first metal layer is exposed in the first opening and the second metal layer is exposed in the second opening, wherein the third-time etching process is a maskless etching process;

forming an interconnection layer, wherein the interconnection layer is electrically connected with the first and second metal layers through the first and second openings; and

forming a lead-out layer, wherein the lead-out layer is located over the first wafer and electrically connected with the interconnection layer.

The present invention further provides the semiconductor device, comprising:

a first wafer and a second wafer, wherein the first wafer comprises a first substrate, a first dielectric layer and a first metal layer; the second wafer comprises a second substrate, a second dielectric layer and a second metal layer, the first dielectric layer facing the second dielectric layer;

a first opening and a second opening, wherein the first opening penetrates through the first substrate and is located above the first metal layer; the second opening penetrates through the first substrate, the first dielectric layer and a partial thickness of the second dielectric layer and is located above the second metal layer;

an interconnection layer, formed in the first opening and the second opening, wherein the interconnection layer is electrically connected with the first layer and second metal layers; and

a lead-out layer, formed over the first wafer, wherein the lead-out layer is electrically connected with the interconnection layer in the first and second openings.

The present invention provides a semiconductor device in which the first opening penetrates through the first substrate and is located above the first metal layer; and the second opening penetrates through the first substrate, the first dielectric layer and a partial thickness of the second dielectric layer, and is located above the second metal layer. The first and second openings do not directly interconnect with each other, that is, the first and second openings are transversely separated, i.e., not aligned or overlapped with each other in a longitudinal direction. Instead, the first metal layer and the second metal layer are electrically connected through an interconnection layer, namely, a transverse connection, which is not limited or constrained by the transverse fabrication process of a TSV nested opening, thus the flexibility of wafer design is improved. Besides, in the present invention, the first opening, which penetrates through the first substrate and is a shallow opening, is filled with a filling layer, so that the problem encountered when filling and removing a filling layer in a deep opening in a TSV nested opening structure is solved.

In addition, the present invention forms the first opening and the second opening through a first etching and a second etching. The first metal layer below the first opening and the second metal layer below the second opening are exposed through a third etching process. The third etching process is a maskless etching (not needed to adopt a photomask). According to the present invention, compared with a traditional TSV nested opening structure adopting three photomasks, one photomask is omitted, and therefore the complexity of the fabrication process is reduced, and a production cost is lowered.

### BRIEF DESCRIPTION OF THE DRAWINGS

FIG. 1 is a schematic sectional view after an upper wafer and a lower wafer are bonded in an existing TSV nested structure forming method;

FIG. 2 is a schematic sectional view after a first opening is formed in the existing TSV nested structure forming method;

FIG. 3 is a schematic sectional view after a second opening is formed in the existing TSV nested structure forming method;

FIG. 4 is a schematic sectional view obtained after filling of a BARC in the existing TSV nested opening structure forming method;

FIG. 5 is a schematic sectional view obtained after back-etching of the BARC in the existing TSV nested opening structure forming method;

FIG. 6 is a schematic sectional view obtained after coating of a photoresist layer in the existing TSV nested opening structure forming method;

FIG. 7 is a schematic sectional view after a photoresist opening is formed in the existing TSV nested opening structure forming method;

FIG. 8 is a schematic sectional view after a third opening is formed in the existing TSV nested opening structure forming method;

FIG. 9 is a schematic sectional view after the BARC and the photoresist layer are removed in the existing TSV nested opening structure forming method;

FIG. 10 is a schematic sectional view after a first metal layer and a second layer are exposed in the existing TSV nested opening structure forming method;

FIG. 11 is a schematic sectional view after an interconnection layer is formed in the existing TSV nested opening structure forming method;

FIG. 12 is a schematic sectional view after a lead-out layer is formed in the existing TSV nested opening structure forming method;

FIG. 13 is a schematic sectional view of the cavities occurred during filling and removing of the BARC in the existing TSV nested opening structure;

FIG. 14 is a flowchart of a method for fabricating a semiconductor device of an embodiment of the present invention;

FIG. 15 is a schematic sectional view of the device after a first wafer and a second wafer are bonded in the embodiment of the present invention;

FIG. 16 is a schematic sectional view after a first opening is formed in the embodiment of the present invention;

FIG. 17 is a schematic sectional view obtained after filling of a BARC of the first opening in the embodiment of the present invention;

FIG. 18 is a schematic sectional view obtained after back-etching of the BARC of the first opening in the embodiment of the present invention;

FIG. 19 is a schematic sectional view after a patterned photoresist is formed in the embodiment of the present invention;

FIG. 20 is a schematic sectional view after a second opening is formed in the embodiment of the present invention;

FIG. 21 is a schematic sectional view after an isolating layer is formed in the embodiment of the present invention;

FIG. 22 is a schematic sectional view after metal layers are exposed through etching in the embodiment of the present invention;

FIG. 23 is a schematic sectional view after the interconnection layer is formed in the first opening and the second opening in the embodiment of the present invention; and

FIG. 24 is a schematic sectional view after the lead-out layer is formed to achieve metal interconnection in the embodiment of the present invention;

### LIST OF REFERENCE NUMERALS

101—first substrate; 102—first dielectric layer; 103—first metal layer; 104—first etching stopping layer;
102a—first portion of the first dielectric layer; 102b—second portion of the first dielectric layer;
201—second substrate; 202—second dielectric layer; 203—second metal layer; 204—second etching stopping layer;
202a—first portion of the second dielectric layer; 202b—second portion of the second dielectric layer;
205—BARC; 206—photoresist layer; 206′—photoresist opening; 207—interconnection layer; 208—lead—out layer;
209—cavity;
70—bonding interface;
51—first opening; 52—second opening; 53—third opening;
301—second substrate; 302—second dielectric layer; 303—second metal layer; 304—second etching stopping layer;
302a—first portion of the second dielectric layer; 302b—second portion of the second dielectric layer;
401—first substrate; 402—first dielectric layer; 403—first metal layer; 404—first etching stopping layer;
402a—first portion of the first dielectric layer; 402b—second portion of the first dielectric layer;
405—oxidizing layer; 406—nitriding layer; 407—BARC; 408—photoresist; 408′—photoresist opening;
409—isolating layer; 410—interconnection layer; 411—third dielectric layer; 412—connecting opening; 413—lead—out layer;
80—bonding interface;
61—first opening; 62—second opening.

### DETAILED DESCRIPTION

As mentioned in the background, a limitation exists when using a current TSV nested opening structure to achieve a metal interconnection in practical applications. In terms of the reason, a deep opening used together with a shallow opening is adopted for the TSV nested opening structure, and metal layers of upper and lower wafers are connected through a TSV nested opening interconnected in a longitudinal direction. During a design, the metal layers of the upper and lower wafers are limited and constrained by the transverse fabrication process of the TSV nested opening interconnected in the longitudinal direction. For example, a transverse distance of the metal layers of the upper and lower wafers cannot be too far. If the transverse distance of the metal layers of the upper and lower wafers is too far, an effective area of the upper wafer is wasted for an opening connection. Meanwhile, with an increased depth-to-width ratio of the deep opening, a difficulty in the filling and removing of a filling layer in the deep opening is increased as well. Thus, only a low flexibility is provided in the design of a wafer adopting the TSV nested opening structure, and meanwhile with an increased depth-to-width ratio of the deep opening, a difficulty of the fabrication process is increased.

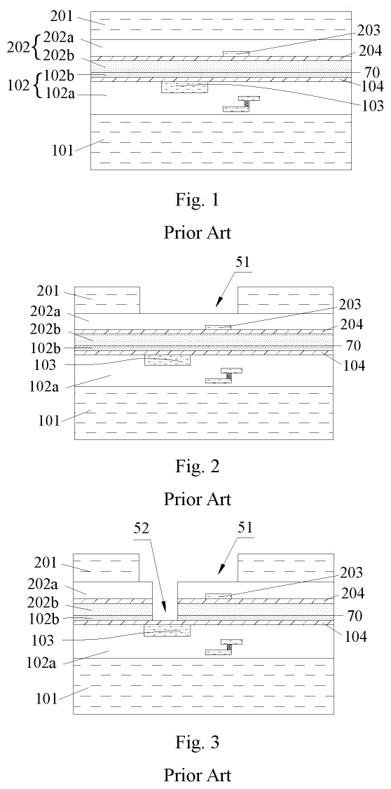

Specifically referring to FIGS. 1-12, an existing method for forming a TSV nested structure comprises the following steps.

Firstly, as shown in FIG. 1, an upper wafer and a lower wafer are bonded, and a bonding interface 70 is formed therebetween, wherein the upper wafer is in an inverted state. The lower wafer comprises a first substrate 101, a first dielectric layer 102 and a first metal layer 103. The upper wafer comprises a second substrate 201, a second dielectric layer 202 and a second metal layer 203, and the first dielectric layer 102 faces the second dielectric layer 202. The first dielectric layer 102 comprises a first portion of the first dielectric layer 102a and a second portion of the first dielectric layer 102b, and the first metal layer 103 is embedded between the first portion of the first dielectric layer 102a and the second portion of the first dielectric layer 102b. The second dielectric layer 202 comprises a first portion of the second dielectric layer 202a and a second portion of the second dielectric layer 202b, and the second metal layer 203 is embedded between the first portion of the second dielectric layer 202a and the second portion of the second dielectric layer 202b. The lower wafer further comprises a first etching stopping layer 104, and the first etching stopping layer 104 is located between the first metal layer 103 and the second portion of the first dielectric layer 102a; and the upper wafer further comprises a second etching stopping layer 204, and the second etching stopping layer 204 is located between the second metal layer 203 and the second portion of the second dielectric layer 202b.

Then, as shown in FIG. 2, a first photolithography and etching process is performed. The first etching terminates at the first portion of the second dielectric layer 202a so that a first opening 51 is formed. The first opening 51 penetrates through the second substrate 201, and is located right above the first metal layer 103 and the second metal layer 203 with a surface of the first portion of the second dielectric layer 202a being exposed in the first opening 51.

Then, as shown in FIG. 3, a second photolithography and etching process is performed. The second etching terminates at the first etching stopping layer 104 so that a second opening 52 is formed. The second opening 52 penetrates through the second dielectric layer 202 and the second portion of the first dielectric layer 102b with a surface of the first etching stopping layer 104 being exposed in the second opening 52. The second opening 52 interconnects with the first opening 51.

Then, as shown in FIG. 4, the first opening 51 and the second opening 52 are filled with a bottom anti reflective coating (BARC) 205, and a surface of the second substrate 201 is further covered with the BARC 205.

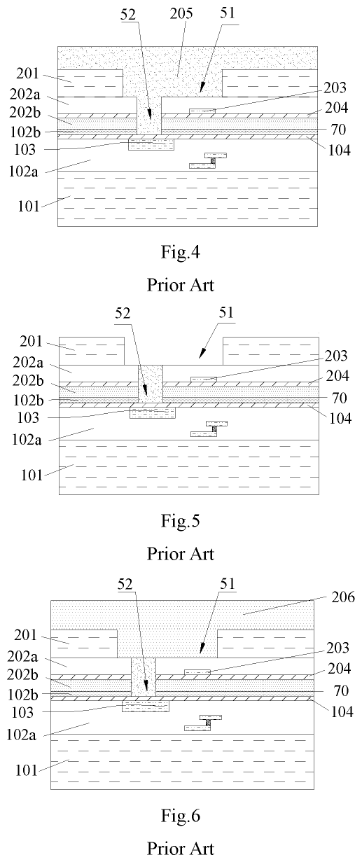

Then, as shown in FIG. 5, the BARC over the surface of the second substrate 201 and in the first opening 51 is removed through back-etching, and a top surface of a remaining BARC is flush with a surface of the first portion of the second dielectric layer 202a.

Then, as shown in FIG. 6, the first opening 51 is coated with a photoresist layer 206, and the surface of the second substrate 201 is further covered with the photoresist layer 206.

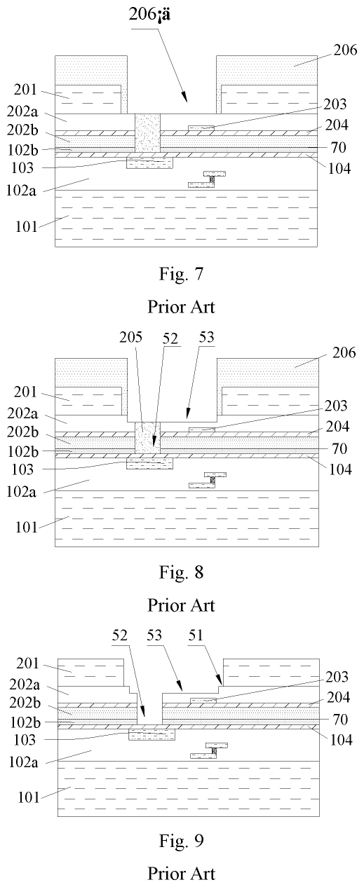

Then, as shown in FIG. 7 and FIG. 8, the photoresist layer 206 is patterned so as to form a photoresist opening 206′. The patterned photoresist layer 206 is used as a mask to perform a third etching process. A part of the first portion of the second dielectric layer 202a is etched away through the third etching process so that a third opening 53 is formed.

Then, the BARC 205 in the second opening 52 and the photoresist layer 206 are removed, which is as shown in FIG. 9.

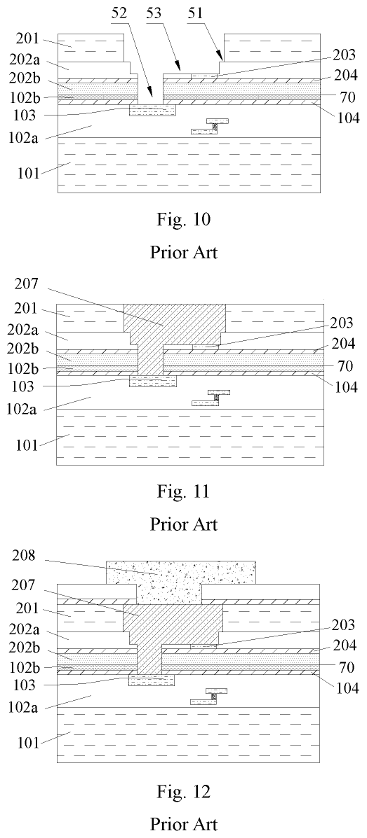

Then, as shown in FIG. 9 and FIG. 10, a dry etching process is performed. A part of the first etching stopping layer 104 located at a bottom of the second opening 52 is removed, meanwhile, a part of the first portion of the second dielectric layer 202a exposed by the third opening 53 and covering the second metal layer 203 is further removed, and therefore the second metal layer 203 and the first metal layer 103 are exposed, so as to form a TSV nested opening structure composed of the first opening 51, the second opening 52 and the third opening 53.

Then, as shown in FIG. 11, a TSV nested opening is filled with an interconnection layer 207, and an electrical connection of the second metal layer 203 and the first metal layer 103 is achieved through the interconnection layer 207.

Finally, as shown in FIG. 12, a lead-out layer 208 is formed above the interconnection layer 207 so as to lead out a signal.

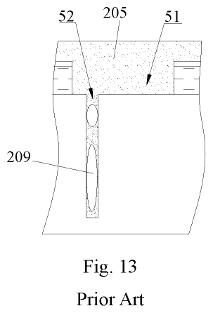

However, the inventor finds that a depth-to-width ratio of the second opening 52 formed by this method is relatively large. As shown in FIG. 13, when the depth of the second opening 52 is increased, a difficulty in the filling of the BARC 205 is increased. Specifically, the deeper second opening 52 cannot be easily filled with the BARC 205, and a cavity 209 can occur. Moreover, a difficulty in the removing of the BARC 205 is increased accordingly.

On the other hand, when the first metal layer 103 and the second metal layer 203 are connected through a TSV nested opening extending in the longitudinal direction, a distribution of the first metal layer 103 and the second metal layer 203 are limited by the position of the TSV nested opening. If a transverse distance of the two metal layers is too far, in order to achieve an electrical connection of the two metal layers, a transverse size of the TSV nested opening is required to be larger, which results in a waste of an effective area of the wafer.

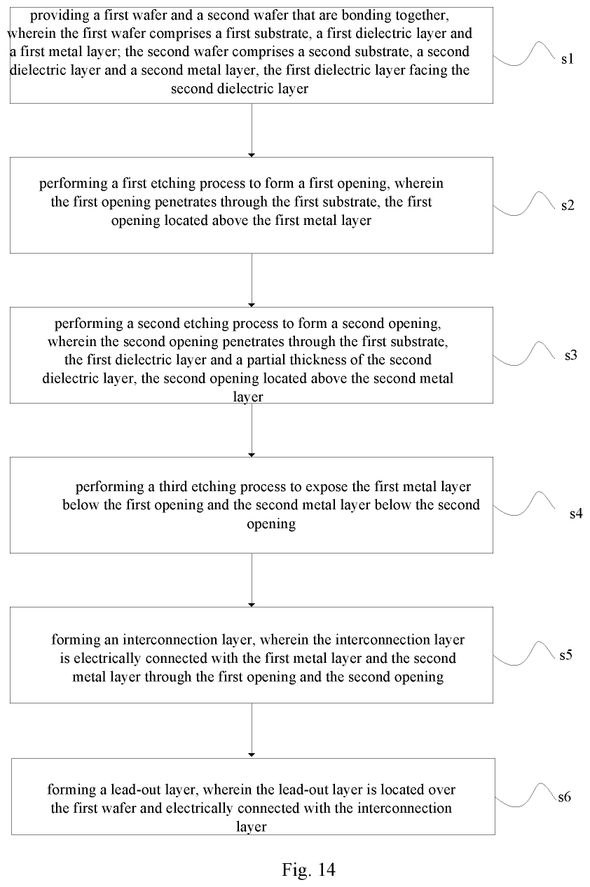

Based on the above research, an embodiment of the present invention provides a semiconductor device fabrication method, as shown in FIG. 14, comprising the following steps:

S1, providing a first wafer and a second wafer that are bonding together, wherein the first wafer comprises a first substrate, a first dielectric layer and a first metal layer; the second wafer comprises a second substrate, a second dielectric layer and a second metal layer, the first dielectric layer facing the second dielectric layer;

S2, performing a first etching process to form a first opening, wherein the first opening penetrates through the first substrate, the first opening located above the first metal layer;

S3, performing a second etching process to form a second opening, wherein the second opening penetrates through the first substrate, the first dielectric layer and a partial thickness of the second dielectric layer, the second opening located above the second metal layer;

S4, performing a third etching process to deepen the first and second openings such that the first metal layer is exposed in the first opening and the second metal layer is exposed in the second opening;

S5, forming an interconnection layer, wherein the interconnection layer is electrically connected with the first metal layer and the second metal layer through the first opening and the second opening; and

S6, forming a lead-out layer, wherein the lead-out layer is located over the first wafer and electrically connected with the interconnection layer.

The present invention provides a semiconductor device, wherein a first opening penetrates through a first substrate and is located above a first metal layer; a second opening penetrates through the first substrate; a first dielectric layer and a partial thickness of a second dielectric layer and is located above a second metal layer. The first opening and the second opening do not directly interconnect with each other, that is, the first opening and the second opening are transversely separated, i.e., not aligned or overlapped with each other in a longitudinal direction. Instead, the first metal layer and the second metal layer are electrically connected through an interconnection layer, namely, a transverse connection, which is not limited or constrained by the transverse fabrication process of a TSV nested opening, thus the flexibility of a wafer design is improved. Besides, in the present invention, the first opening which penetrates through the first substrate and is a shallow opening, is filled with a filling layer, so that the problem encountered when filling and removing of the filling layer in a deep opening in a TSV nested opening structure opening is solved.

The present invention is further illustrated in detail in conjunction with the drawings and the specific embodiments. According to the following illustration, the advantages and the features of the prevent invention will be more clear. It is noted that the figures are provided in a very simplified form and not necessarily drawn to scale, with the only intention to facilitate convenience and clarity in explaining the embodiments of the present invention.

It needs to be explained that when two wafers are stacked, it is always the case that one wafer is located on an upper portion and one wafer is located on a lower portion, but which wafer of the first wafer and the second wafer must be placed on the upper portion/lower portion is not limited in the present invention, and positions of the upper wafer and the lower wafer can be interchanged. Herein, for the purpose of simple and convenient description, only one position relationship of the two wafers is shown, which can be understood by those skilled in the art, all the technical content described herein is also applicable to a situation that positions of “the first wafer” and “the second wafer” are reversed up and down, and at this moment, a position relationship of each layer of a stacked type semiconductor device is also correspondingly reversed up and down. In some cases, preferably, during a bonding process which is performed on the two wafers, the wafer with a larger wafer bow is placed on the lower portion. However, in this case, after bonding of the wafers ends, whether to reverse up and down or not can also be determined according to actual demands, and therefore which wafer is on the upper portion and which wafer is on the lower portion are determined finally.

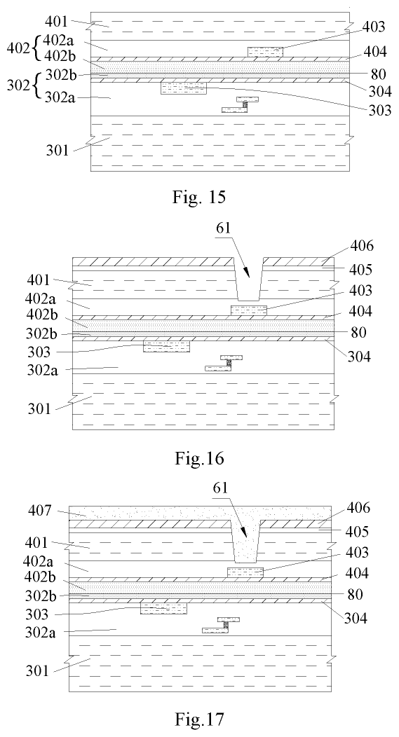

As shown in FIG. 15, in step S1, providing a first wafer and a second wafer that are bonded together. The first wafer and the second wafer form a bonding interface 80.

The first wafer comprises a first substrate 401, a first dielectric layer 402 and a first metal layer 403. The second wafer comprises a second substrate 301, a second dielectric layer 302 and a second metal layer 303. The first dielectric layer 402 faces the second dielectric layer 302. The first dielectric layer 402 comprises a first portion of the first dielectric layer 402a and a second portion of the first dielectric layer 402b, and the first metal layer 403 is embedded between the first portion of the first dielectric layer 402a and the second portion of the first dielectric layer 402b. The second dielectric layer 302 comprises a first portion of the second dielectric layer 302a and a second portion of the second dielectric layer 302b, and the second metal layer 303 is embedded between the first portion of the second dielectric layer 302a and the second portion of the second dielectric layer 302b. The first wafer further comprises a first etching stopping layer 404, and the first etching stopping layer 404 is located between the first metal layer 403 and the second portion of the first dielectric layer 402b. The second wafer further comprises a second etching stopping layer 304. The second etching stopping layer 304 is located between the second metal layer 303 and the second portion of the second dielectric layer 302b.

Preferably, after the two wafers are bonded, thinning is further performed on a first wafer and/or a second wafer.

It should be understood that herein, serial numbers such as “first”, “second”, “third”, and “fourth” are just used for distinguishing different parts with same names or processes with same names, and do not mean a sequence, or a position relationship or the like. In addition, for the different parts with the same names, such as a “first substrate” and a “second substrate” and a “first dielectric layer” and a “second dielectric layer”, it does not mean that they have a same structure or part. For example, although not shown in the drawings, in most cases, parts formed in the “first substrate” and the “second substrate” are different, and the substrates may also be different in structure. In some embodiments, the substrate may be a semiconductor substrate, and is made from any semiconductor material (such as Si, SiC and SiGe) suitable for a semiconductor device. In some other embodiments, the substrate may also be various composite substrates such as silicon on insulator (SOI), and germanium and silicon on insulator. Those skilled in the art would understand that the substrate is not limited by any way, and can be selected according to practical application. Various device (not limited to a semiconductor device) components (not shown in the drawings) can be formed in the substrate. It may also be that other layers or components, such as a gate structure, a contact hole, a dielectric layer, a metal connection wire and a through hole, have been formed on the substrate.

As shown in FIG. 16, a dielectric layer is formed over a surface of the first substrate 401. The dielectric layer may comprise an oxidizing layer 405 formed over the first substrate 401 and a nitriding layer 406 formed over the oxidizing layer 405. The nitriding layer 406 plays a protective role and serves as a passivating layer, and the oxidizing layer 405 plays a role of relieving stress of the nitriding layer 406.

Then, a first photolithography and etching process is performed. The first etching terminates at the first portion of the first dielectric layer 402a, and a first opening 61 is formed. The first opening 61 penetrates through the first substrate 401, and is located right above the first metal layer 403 with a surface of the first portion of the first dielectric layer 402a being exposed in the first opening 61.

As shown in FIG. 17, a filling layer is formed. The filling layer in the embodiment is a bottom anti reflective coating (BARC) 407. The first opening 61 is filled with the filling layer 407, and a surface of the nitriding layer 406 is covered with the filling layer 407.

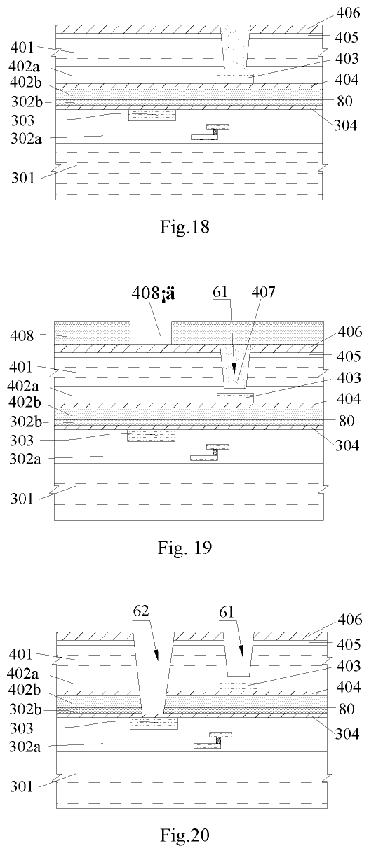

As shown in FIG. 18, a back-etching process is performed, and the BARC over the surface of the nitriding layer 406 is removed.

As shown in FIG. 19, a patterned photoresist 408 is formed over the surface of the nitriding layer 406 so as to form a photoresist opening 408′. The photoresist opening 408′ is located above the second metal layer 303.

As shown in FIG. 19 and FIG. 20, a second etching process is performed and terminates at the second etching stopping layer 304 to form a second opening 62. The second opening 62 penetrates through the first substrate 401, the first dielectric layer 402 and the second portion of the second dielectric layer 302b, and is located above the second metal layer 303. Then, the photoresist 408 over the surface of the nitriding layer 406 and the bottom anti reflective coating 407 in the first opening 61 are removed, and a structure obtained after the removal is as shown in FIG. 20.

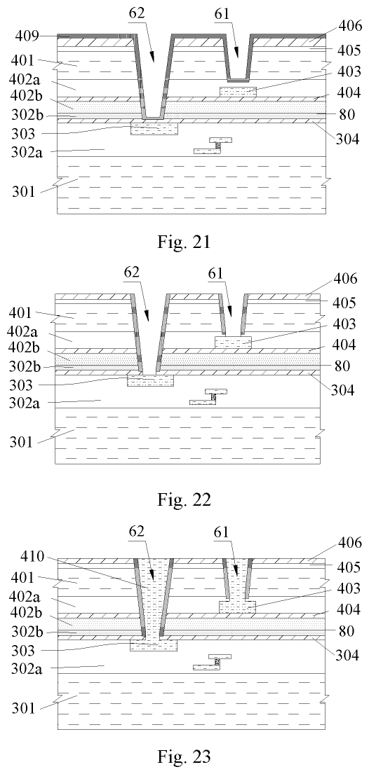

As shown in FIG. 21, an isolating layer 409 is formed over the surface of the nitriding layer 406. And a surface of each of the first opening 61 and the second opening 62 as well as the surface of the nitriding layer 406 is covered by the isolating layer 409.

As shown in FIG. 22, a third etching process is performed. A maskless dry etching (without needing a photomask) is adopted for the third etching. The isolating layer at a bottom of the first opening 61 and a bottom of the second opening 62 and over the surface of the nitriding layer 406 are removed with the first metal layer 403 being exposed in the first opening 61 and the second metal layer 303 being exposed in the second opening 62. Due to the fact that in this embodiment, the third etching is a maskless etching process (without needing a photomask), thus compared with a traditional TSV nested opening structure adopting three photomasks, one photomask will be omitted in this application. Therefore the complexity of the fabrication process is reduced, and production cost is lowered.

As shown in FIG. 23, an interconnection layer 410 is formed, for example, the first opening 61 and the second opening 62 are filled with the interconnection layer 410 and the surface of the nitriding layer 406 is covered by the interconnection layer 410. Then a chemical and mechanical planarization process is performed to remove the interconnection layer on the surface of the nitriding layer 406. The interconnection layer 410 is electrically connected with the first metal layer 403 and the second metal layer 303 through the first opening 61 and the second opening 62. The interconnection layer 410 is a conductive material which may be copper or a copper alloy; for example, filling of the first opening 61 and the second opening 62 is achieved by adopting a copper electroplating manner.

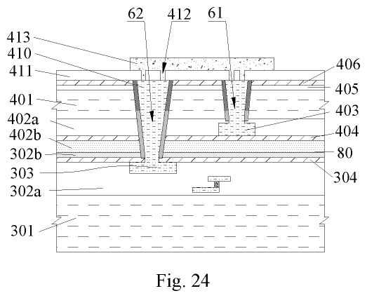

As shown in FIG. 24, a lead-out layer 413 is formed. The lead-out layer 413 is located on the first wafer and electrically connected with the interconnection layer 410. During specific embodiment, specific steps for forming the lead-out layer 413 comprise, for example, firstly forming a third dielectric layer 411, wherein the third dielectric layer 411 is located over the surface of the nitriding layer 406; then performing a fourth etching process to form a connection hole 412, wherein the connection opening 412 penetrates through the third dielectric layer 411 and is located above the first opening 61 and the second opening 62; and then forming the lead-out layer 413, wherein the lead-out layer 413 is electrically connected with the interconnection layer 410 in the first opening 61 and the second opening 62 through the connection opening 412. The lead-out layer 413 may be an aluminum layer, and is formed in a manner that the aluminum is deposited over an entire surface of the third dielectric layer 411, and then back-etching is performed.

The semiconductor device of this embodiment of the present invention, as shown in FIG. 24, comprises:

a first wafer and a second wafer, wherein the first wafer comprises a first substrate 401, a first dielectric layer 402 and a first metal layer 403; the second wafer comprises a second substrate 301, a second dielectric layer 302 and a second metal layer 303, the first dielectric layer 402 facing the second dielectric layer 302;

a first opening 61 and a second opening 62, wherein the first opening 61 penetrates through the first substrate 401 and is located above the first metal layer 403; the second opening 62 penetrates through the first substrate 401, the first dielectric layer 402 and a partial thickness of the second dielectric layer 302 and is located above the second metal layer 303;

an interconnection layer 410, formed in the first opening 61 and the second opening 62, wherein the interconnection layer 410 is electrically connected with the first metal layer 403 and the second metal layer 303; and

a lead-out layer 412, formed over the first wafer 40, wherein the lead-out layer 412 is electrically connected with the interconnection layer 410 in the first opening 61 and the second opening 62.

Cross sections, perpendicular to surfaces of the first wafer and the second wafer, of the first opening 61 and the second opening 62 comprise an inverted trapezoid shape.

In addition, although only one electrical connection structure between the two metal layers of the semiconductor device is shown in the FIG. 24, those skilled in the art would understand that at least one electrical connection structure between the two metal layers needs to be formed so as to achieve metal interconnection between two wafers.

To sum up, after the first wafer and the second wafer are bonded in the present invention, the dielectric layer is formed; then the etching process is performed twice, so that the first opening is formed above the first metal layer of the first wafer, and the second opening is formed above the second metal layer of the second wafer with the metal layers being unexposed; then an isolating film is formed, further the metal layers of the first wafer and the second wafer are exposed at the same time through dry etching; the two openings are filled with metal copper in an copper electroplating manner, and chemical and mechanical planarization is performed; later, the dielectric layer is deposited over the surface of the wafer, playing an insulating and protective role, and then photolithography and etching process is performed over the dielectric layer to form the connection opening; and finally, a metal thin film is deposited, and etching is performed so as to achieve the metal interconnection and signal lead-out between the two wafers.

The above description only describes favorable exemplary embodiments of the present invention, and is not intended to limit any of the scope of the present invention. Any variation and modification made by those skilled in the art of the present invention according to the above disclosed content belong to the protection scope of the claims.

What is claimed is:

1. A method for fabricating a semiconductor device, comprising:
providing a first wafer and a second wafer that are bonded together, wherein the first wafer comprises a first substrate, a first dielectric layer and a first metal layer; the second wafer comprises a second substrate, a second dielectric layer and a second metal layer, the first dielectric layer facing the second dielectric layer;
performing a first etching process to form a first opening, wherein the first opening penetrates through the first substrate, the first opening located above the first metal layer;
performing a second etching process to form a second opening, wherein the second opening penetrates through the first substrate, the first dielectric layer and a partial thickness of the second dielectric layer, the second opening located above the second metal layer;
performing a third etching process to deepen the first and second openings such that the first metal layer is exposed in the first opening and the second metal layer is exposed in the second opening;
forming an interconnection layer, wherein the interconnection layer is electrically connected with the first and second metal layers through the first and second openings; and
forming a lead-out layer, wherein the lead-out layer is located over the first wafer and electrically connected with the interconnection layer.

2. The method according to claim 1, further comprising, subsequent to the formation of the first opening and prior to the formation of the second opening:
forming a filling layer, wherein the first opening is filled with the filling layer.

3. The method according to claim 2, wherein forming the filling layer comprises the steps of:
forming a bottom anti reflective coating layer, wherein the first opening is filled with the bottom anti reflective coating layer and a surface of the first wafer is covered by the bottom anti reflective coating layer; and
performing a back-etching process to remove the bottom anti reflective coating layer over the surface of the first wafer.

4. The method according to claim 1, further comprising, prior to performing the third etching process:
forming an isolating layer, wherein a surface of each of the first and second openings, and a surface of the first wafer is covered by the isolating layer;
wherein portions of the isolating layer at bottoms of the first and second openings as well as over the surface of the first wafer are removed when the third etching process is performed.

5. The method according to claim 1, wherein the third etching process is a maskless etching process.

6. The method according to claim 1, wherein forming the lead-out layer comprises the steps of:
forming a third dielectric layer, wherein the third dielectric layer is located on the first wafer;
performing a fourth etching process to form a connection opening, wherein the connection opening penetrates through the third dielectric layer and is located above the first and second openings; and
forming the lead-out layer, wherein the lead-out layer is electrically connected with the interconnection layer in the first and second openings through the connection opening.

7. The method according to claim 1, wherein forming the interconnection layer comprises the steps of:
depositing an interconnection material, wherein the first and second openings are filled with the interconnection material and a surface of the first wafer is covered by the interconnection material; and
performing a chemical and mechanical planarization process to remove a portion of the interconnection material over the surface of the first wafer to form the interconnection layer.

8. The method according to claim 1, wherein the first dielectric layer comprises a first portion of the first dielectric layer and a second portion of the first dielectric layer; the first metal layer is embedded between the first portion of the first dielectric layer and the second portion of the first dielectric layer; the second dielectric layer comprises a first portion of the second dielectric layer and a second portion of the second dielectric layer; a second metal layer is embedded between the first portion of the second dielectric layer and the second portion of the second dielectric layer; the first wafer further comprises a first etching stopping layer, the first etching stopping layer located between the first metal layer and the second portion of the first dielectric layer; and the second wafer further comprises a second etching stopping layer, the second etching stopping layer located between the second metal layer and the second portion of the second dielectric layer.

9. A semiconductor device, comprising:
a first wafer and a second wafer, wherein the first wafer comprises a first substrate, a first dielectric layer and a first metal layer; the second wafer comprises a second substrate, a second dielectric layer and a second metal layer, the first dielectric layer facing the second dielectric layer;
a first opening and a second opening, wherein the first opening penetrates through the first substrate and is located above the first metal layer; the second opening penetrates through the first substrate, the first dielectric layer and a partial thickness of the second dielectric layer, and is located above the second metal layer;
an interconnection layer, formed in the first opening and the second opening, wherein the interconnection layer is electrically connected with the first and second metal layers; and
a lead-out layer, formed over the first wafer, wherein the lead-out layer is electrically connected with the interconnection layer in the first and second openings.

10. The semiconductor device according to claim 9, wherein a cross section, perpendicular to surfaces of the first and second wafers, of each of the first and second openings comprises an inverted trapezoid shape.
